(19) United States
(12) Patent Application Publication
(10) Pub. No.: US 2026/0360966 A1
(43) Pub. Date: Nov. 12, 2026

(54) ANTENNA PACKAGE AND IMAGE DISPLAY DEVICE INCLUDING THE SAME

(71) Applicant: DONGWOO FINE-CHEM CO., LTD., Jeollabuk-do (KR)

(72) Inventors: DAE KYU KIM, Jeollabuk-do (KR); MEE AE HUR, Jeollabuk-do (KR); HEE JUN PARK, Jeollabuk-do (KR); KI HUN SUNG, Jeollabuk-do (KR)

(21) Appl. No.: 19/488,948

(22) PCT Filed: May 27, 2024
(86) PCT No.: PCT/KR2024/007138

§ 371 Date: Dec. 1, 2025

(30) Foreign Application Priority Data
Jun. 1, 2023 (KR) 10-2023-0070609

(51) Int. Cl. H01Q 1/24; H01Q 21/06; H05K 1/03; H05K 1/14; H05K 1/181

(52) U.S. Cl. CPC H01Q 1/243; H01Q 21/06; H05K 1/0393; H05K 1/144; H05K 1/147; H05K 1/181; H05K 2201/041; H05K 2201/10098

(57) ABSTRACT

An antenna package includes a first circuit board, a second circuit board stacked on the top surface of the first circuit board and having higher flexibility than the first circuit board, an antenna driving integrated circuit chip mounted on the second circuit board, and an antenna element bonded to the second circuit board and electrically connected to the antenna driving integrated circuit chip. Through a combination of the first and second printed circuit boards, an antenna signal path can be shortened, and circuit connection reliability and signal efficiency can be improved.

### BACKGROUND

### 1. Technical Field

The present invention relates to an antenna package and an image display device including the same. More particularly, the present invention relates to an antenna package including a circuit board and an integrated circuit chip, and an image display device including the same.

### 2. Background Art

As information technologies have recently been developed, a wireless communication technology such as Wi-Fi, Bluetooth, etc., is combined with an image display device to be implanted in the form of, e.g., a smartphone. In this case, an antenna may be coupled to the image display device to perform communication functions.

With recent advancements in mobile communication technologies, an antenna for high-frequency or ultra-high-frequency communication corresponding to, e.g., 3G or more, or 5G or more is required to be coupled to the image display device.

However, as an operating frequency of the antenna increases, a signal loss may increase, and the signal loss may be further increased as a length of a transmission path increases.

Additionally, if an intermediate circuit structure such as a flexible printed circuit board (FPCB) is used to electrically connect the antenna and a driving integrated circuit chip for antenna feeding/drive control, an additional signal loss may occur.

To mount the driving integrated circuit chip, an additional circuit board may be added in addition to the FPCB. In this case, a signal path between the antenna and the driver integrated circuit chip may be further increased to further increase the signal loss.

Further, as the image display device become thinner and a display area increase, a space available for introducing the antenna may be decreased.

For example, Korean Published Patent Application No. 2003-0095557 discloses an antenna structure embedded into a portable terminal, but an antenna construction that can prevent the signal loss and implement high-frequency operation within a limited space is required.

### SUMMARY

According to an aspect of the present invention, there is provided an antenna package having improved operational reliability and signal efficiency.

According to an aspect of the present invention, there is provided an image display device including an antenna package with improved operational reliability and signal efficiency.
1. An antenna package including a first circuit board, a second circuit board stacked on a top surface of the first circuit board, the second circuit board having a ductility higher than that of the first circuit board; an antenna driving integrated circuit chip mounted on the second circuit board; and an antenna element bonded to the second circuit board and electrically connected to the antenna driving integrated circuit chip.
2. The antenna package of the above 1, wherein the second circuit board is a flexible printed circuit board, and the first circuit board is a rigid printed circuit board.
3. The antenna package of the above 1, wherein the first circuit board includes repeatedly stacked insulating layers and wiring layers, and wherein the second circuit board includes a core layer, and a first conductive layer formed on a top surface of the core layer, and the first conductive layer includes an antenna signal wiring bonded to the antenna element.
4. The antenna package of the above 3, wherein the insulating layer of the first circuit board has a higher hardness or a lower ductility than that of the core layer of the second circuit board.
5. The antenna package of the above 3, wherein the driving integrated circuit chip is directly mounted on the antenna signal wiring.
6. The antenna package of the above 3, wherein the second circuit board further includes a barrier layer covering the antenna signal wiring.
7. The antenna package of the above 6, wherein the second circuit board has a first portion overlapping the first circuit board and a second portion that does not overlap the first circuit board, and the barrier layer is formed throughout the first portion and the second portion.
8. The antenna package of the above 7, wherein an end portion of the second portion of the second circuit board has a bonding region bonded to the antenna element, and the barrier layer is spaced apart from the bonding region with a gap therebetween on the second portion of the second circuit board
9. The antenna package of the above 6, wherein the driving integrated circuit chip includes antenna connection terminals connected to the antenna signal wiring, and the barrier layer is filled between the antenna connection terminals.
10. The antenna package of the above 3, wherein the antenna element includes an antenna dielectric layer and a plurality of antenna units formed on the antenna dielectric layer, and
the antenna signal wiring of the second circuit board includes a plurality of antenna signal wirings connected to each of the antenna units.
11. The antenna package of the above 10, wherein the antenna units include at least one transmit antenna unit and a plurality of receiving antenna units.
12. The antenna package of the above 10, wherein the first conductive layer further includes a horizontal ground layer spaced apart from the antenna signal wirings and arranged around the antenna signal wirings.
13. The antenna package of the above 3, wherein the second circuit board further includes a second conductive layer formed on a bottom surface of the core layer to overlap the antenna signal wirings.
14. The antenna package of the above 3, wherein the driving integrated circuit chip includes an antenna connection terminal connected to the antenna signal wiring, and an internal circuit terminal connected to the wiring layer.
15. The antenna package of the above 14, wherein the first circuit board and the second circuit board each further includes a via structure connecting the internal circuit terminal to the wiring layer.
16. An image display device including a display panel; and the antenna package according to the above-described embodiments coupled to the display panel so that the antenna element is arranged toward a front portion of the display panel.
17. The image display device of the above 16, wherein the first circuit board and the driver integrated circuit chip are arranged at a rear portion under the display panel, and
the second circuit board is bent to the front portion of the display panel and bonded to the antenna element.

In an antenna package according to embodiments of the present invention, a flexible printed circuit board (FPCB) connected to an antenna element may be stacked on a rigid printed circuit board, and a driving integrated circuit chip may be mounted on the flexible printed circuit board.

Thus, the driving integrated circuit chip and the antenna element may be electrically connected without an additional connection structure such as a via structure and a connector. Accordingly, a feeding path/signal path to the antenna element may be shortened while achieving mechanical rigidity and stability required during the driving integrated circuit chip mounting process.

Further, the rigid printed circuit board and the flexible printed circuit board may become integral with each other, an electronic element such as an RLC circuit element may be packaged within the antenna package, thereby improving a space utilization of an image display device to which the antenna package is applied.

### BRIEF DESCRIPTION OF THE DRAWINGS

FIG. 1 is a schematic cross-sectional view illustrating an antenna package according to example embodiments.

FIG. 2 is a schematic plan view illustrating an antenna package according to example embodiments.

FIG. 3 is a schematic plan view illustrating an antenna element included in an antenna package according to example embodiments.

FIG. 4 is a schematic plan view illustrating an antenna element included in an antenna package according to example embodiments.

FIG. 5 is a schematic partially enlarged plan view illustrating an antenna package according to example embodiments.

FIG. 6 is a schematic cross-sectional view illustrating an antenna package according to example embodiments.

FIG. 7 is a schematic plan view illustrating an image display device according to example embodiments.

FIG. 8 is a schematic cross-sectional view illustrating an image display device according to example embodiments.

FIG. 9 is a schematic cross-sectional view illustrating an antenna package according to a comparative example.

### DETAILED DESCRIPTION

Embodiments of the present invention provide an antenna package including a first circuit board and a second circuit board having different ductilities. Additionally, an antenna package and an image display device including the antenna package are provided.

Hereinafter, embodiments of the present invention will be described in more detail with reference to drawings. However, since the embodiments provided in the present specification provide some preferred examples and serve to further understand the technical concepts of the present invention together with the above-described contents of the present invention, the present invention should not be interpreted by being limited to the matters described in such embodiments.

Terms “first”, “second”, “upper portion”, “lower portion”, “top surface”, “bottom surface” used herein are not intended to specify an absolute position, but to distinguish different elements or relative positions between the different elements.

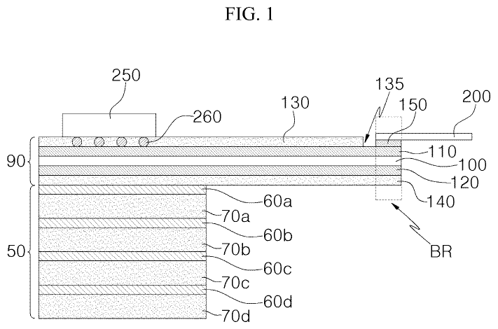

FIG. 1 is a schematic cross-sectional view illustrating an antenna package according to embodiments.

Referring to FIG. 1, the antenna package includes a circuit board stack for an antenna, a driving integrated circuit chip 250 mounted on the circuit board stack for an antenna, and an antenna element 200 electrically connected to the driving integrated circuit chip 250.

The circuit board stack for an antenna may include a first circuit board 50 and a second circuit board 90 stacked on the first circuit board 50.

The first circuit board 50 may have higher hardness or lower ductility than those of the second circuit board 90. In example embodiments, the first circuit board 50 may be a rigid-PCB.

The first circuit board 50 may include insulating layers 70 and wiring layers 60. At least one of the insulating layers 70 may include an inorganic fiber such as glass fiber or a resin (e.g., an epoxy resin) impregnating inorganic particles. For example, the insulating layer 70 may be prepared from a prepreg. For example, the insulating layer 70 may have a glass transition temperature Tg higher than that of a core layer 100 of the second circuit board 90.

A plurality of the insulating layers 70 and a plurality of the wiring layers 60 may be alternately and repeatedly stacked. For example, a first wiring layer 60a, a first insulating layer 70a, a second wiring layer 60b, a second insulating layer 70c, a third insulating layer 70c, a fourth wiring layer 60d, and a fourth insulating layer 70d may be alternately and sequentially stacked in a direction from a top surface to a bottom surface of the first circuit board 50.

The stacked number of the insulating layers 70 and the wiring layers 60 in the first circuit board 50 is not particularly limited, and may be appropriately adjusted in consideration of a circuit integration, a size of the antenna package, etc.

For example, the first circuit board 50 may be prepared from a copper clad laminate (CCL).

The second circuit board 90 may have lower rigidity or higher ductility than those of the first circuit board 50. The second circuit board 90 may include the core layer 100 including a flexible resin and a first conductive layer 110 formed on a top surface of the core layer 100.

For example, the core layer 100 may include a flexible resin such as a polyimide resin, a modified polyimide (MPI), an epoxy resin, polyester, a cyclo olefin polymer (COP), a liquid crystal polymer (LCP), etc. In a preferable embodiment, the core layer 100 may include the polyimide resin or the MPI

In some embodiments, a second conductive layer 120 may be formed on a bottom surface of the core layer 100.

The first and second conductive layers 110 and 120 and the wiring layers 60 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (Fe), iron (Mn), manganese (Co), cobalt (Ni), tin (Sn), zinc (Zn), molybdenum (Mo), calcium (Ca), or an alloy containing at least one metal thereof. In some embodiments, the first and second conductive layers 110 and 120, and the wiring layers 60 may include copper or a copper alloy.

The second circuit board 90 may further include a barrier layer 130 covering the first conductive layer 110. The second circuit board 90 may further include a protection layer 140 covering the second conductive layer 120.

Top and bottom surfaces of the second circuit board 90 may be provided by the barrier layer 130 and the protective layer 140, respectively. For example, the protective layer 140 may be provided as a lower cover-lay film of the second circuit board 90.

The barrier layer 130 and the protective layer 140 may include an organic insulating material or an inorganic insulating material. In some embodiments, the barrier layer 130 and the protective layer 140 may include a flexible resin material.

The driving integrated circuit chip 250 may be mounted on the second circuit board 90. According to embodiments, the driving integrated circuit chip 250 may be directly mounted on the second circuit board 90 through a surface mounting technology (SMT). In example embodiments, the driving integrated circuit chip 250 may be directly mounted on the second circuit board 90 without intermediation of a via hole or a via structure.

Accordingly, a sequential stacked structure of the first circuit board 50—the second circuit board 90—the driving integrated circuit chip 250 may be formed. An upper portion of the circuit board stack for an antenna may be provided by the second circuit board 90, and a lower portion of the circuit board stack for an antenna may be provided by the first circuit board 50.

As described above, the first circuit board 50 may have the relatively high rigidity, and may function as a support board during the mounting process of the driving integrated circuit chip 250. The driving integrated circuit chip 250 may be mounted on a portion of the second circuit board 90 overlapping the first circuit board 50. Accordingly, mechanical and thermal stability may be sufficiently achieved during the chip mounting process including a high-temperature heating such as a soldering process.

The driving integrated circuit chip 250 may include antenna connection terminals 260. The antenna connection terminals 260 may have a conductive ball shape and may form a ball grid array BGA.

The barrier layer 130 may be integrally included in the second circuit board 90, and may protect the first conductive layer 110 during the mounting process.

For example, the antenna connection terminals 260 included in the driving integrated circuit chip 250 may be electrically connected to the first conductive layer 110 by the soldering process. In some embodiments, the antenna connection terminals 260 may be in direct contact with the first conductive layer 110.

In some embodiments, the barrier layer 130 may fill a space between the antenna connection terminals 260. In this case, the barrier layer 130 may be provided as a solder resist.

An end portion of the first conductive layer 110 may be connected to the antenna element 200. In some embodiments, a conductive intermediate structure 150 may be formed between the end portion of the first conductive layer 110 and the antenna element 200. For example, the conductive intermediate structure 150 may include an anisotropic conductive film (ACF).

The barrier layer 130 may partially cover the first conductive layer 110. In example embodiments, the barrier layer 130 may be formed from an overlapping region with the first circuit board 50 throughout a non-overlapping region. In some embodiments, the barrier layer 130 may be spaced apart from a bonding region BR of the antenna element 200 and the second circuit board 90 with a gap 135 interposed therebetween.

Accordingly, a sufficient margin for the bonding process with the antenna element 200 may be sufficiently achieved while preventing cracks/peel-off due to bending of the first conductive layer 110 in the non-overlapping region.

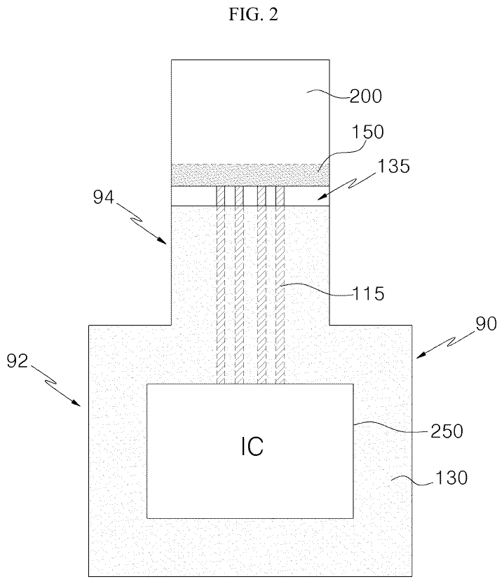

FIG. 2 is a schematic plan view illustrating an antenna package according to embodiments.

Referring to FIG. 2, the second circuit board 90 may include a first portion 92 and a second portion 94. The first portion 92 may correspond to the overlapping region with the first circuit board 50. The second portion 94 may correspond to the non-overlapping region with the first circuit board 94. The second portion 94 may correspond to a bending region of the second circuit board 90.

In some embodiments, the second portion 94 may have a width smaller than that of the first portion 92, and thus may improve bending properties.

The first conductive layer 110 may include at least one antenna signal wiring 115. Feeding and driving signals may be applied from the driving integrated circuit chip 250 to the antenna element 200 through the antenna signal wiring 115. In some embodiments, the first conductive layer 110 may include a plurality of the antenna signal wirings 115. In this case, a plurality of antenna units may be electrically connected to the antenna driving integrated circuit chip 250 through the second circuit board 90.

As described above, the barrier layer 130 of the second circuit board 90 may be formed throughout the first portion 92 and the second portion 94, and may cover the antenna signal wiring 115.

According to the above-described embodiments of the present invention, the driving integrated circuit chip 250 may be directly mounted on the second circuit board 90 bonded to the antenna element 200, and the second circuit board 90 may be stacked on the first circuit board 50 having increased rigidity.

Thus, the signal path between the driving integrated circuit chip 250 and the antenna element 200 may be shortened while omitting a connection structure such as a via structure and a connector added to connect the antenna to the driving integrated circuit chip 250 generally mounted on a rigid-PCB such as the first circuit board 50. Thus, signal loss may be suppressed while increasing a feeding efficiency to the antenna element 200.

Further, the first circuit board 50 may also support the driving integrated circuit chip 250 under the second circuit board 90. Thus, even when the driving integrated circuit chip 250 is mounted on the second circuit board 90 having relatively high flexibility, sufficient supporting force and mounting stability may be provided.

In some embodiments, the second conductive layer 120 may include a ground layer overlapping the antenna signal wirings 115 in a thickness direction with the core layer 100 interposed therebetween. Accordingly, electric field formation and signal transmission around the antenna signal wirings 115 may be promoted, and noises around the antenna signal wirings 115 may be absorbed or shielded.

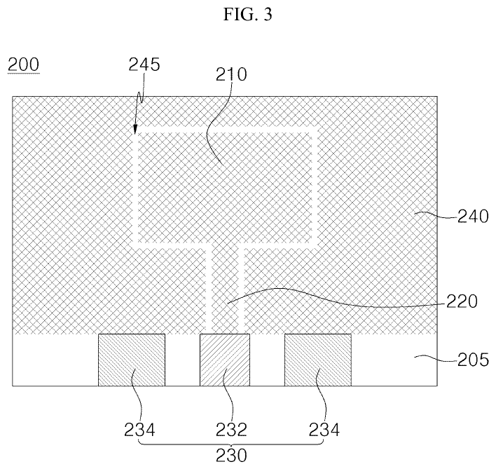

FIG. 3 is a schematic plan view illustrating an antenna element included in an antenna package according to embodiments.

Referring to FIG. 3, the antenna element 200 may include an antenna unit disposed on an antenna dielectric layer 205. The antenna unit may include a radiator 210, a transmission line 220 and a pad 230.

The antenna dielectric layer 205 may include a transparent resin material, e.g., a polyester-based resin such as polyethylene terephthalate, polyethylene isophthalate, polyethylene naphthalate, polybutylene terephthalate, etc.; a cellulose-based resin such as diacetyl cellulose, triacetyl cellulose, etc.; a polycarbonate-based resin; an acrylic resin such as polymethyl (meth)acrylate, polyethyl (meth)acrylate, etc.; a styrene-based resin such as polystyrene, an acrylonitrile-styrene copolymer, etc.; a polyolefin-based resin such as polyethylene, polypropylene, a cycloolefin or polyolefin having a norbornene structure, an ethylene-propylene copolymer, etc.; a vinyl chloride-based resin; an amide-based resin such as nylon, an aromatic polyamide, etc.; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more therefrom.

The antenna dielectric layer 105 may include an adhesive material such as an optically clear adhesive (OCA), an optically clear resin (OCR), etc.

In some embodiments, the antenna dielectric layer 205 may include an inorganic insulating material such as silicon oxide, silicon nitride, silicon oxynitride, glass, etc.

In an embodiment, the antenna dielectric layer 205 may be provided as a substantially single layer. In an embodiment, the antenna dielectric layer 105 may include a multi-layered structure of at least two layers.

An impedance or an inductance of the antenna unit may be formed by the antenna dielectric layer 205 to adjust a frequency band at which driving or sensing of the antenna element 200 may be implemented. In some embodiments, a dielectric constant of the antenna dielectric layer 105 may be adjusted in a range of about 1.5 to 12. When the dielectric constant is greater than about 12, a driving frequency may be excessively reduced and driving in a high/ultra-high frequency band may not be implemented.

In some embodiments, an antenna ground layer (not illustrated) may be formed on a bottom surface of the antenna dielectric layer 205. Generation of an electric field in the transmission line 220 may be further promoted through the antenna ground layer, and electrical noises around the transmission line 220 may be absorbed or shielded.

In some embodiments, the antenna ground layer may be included as a separate component of the antenna element 200. In some embodiments, a conductive member of an image display device to which the antenna element 200 is applied may be provided as the ground layer.

The conductive member may include, for example, a gate electrode, various wirings such as a gate electrode, a scan lines or a data line, or various electrodes such as a pixel electrode and a common electrode included in a thin film transistor (TFT) array included in a display panel.

In an embodiment, a metallic member such as an SUS plate, a sensor member such as a digitizer, and a heat dissipation sheet which may be disposed at a rear portion of the image display device may be provided as the antenna ground layer.

The radiator 210 may have, e.g., a polygonal plate shape, and the transmission line 220 may extend from one side of the radiator 210 and may be electrically connected to a signal pad 232. The transmission line 220 may be formed as a single member substantially integral with the radiator 210.

A shape and a size of the radiator 210 may be designed to transmit/receive signals in the high frequency/ultra-high frequency band (e.g., 3G, 4G, or 5G or more). In some embodiments, a resonance frequency of the radiator 210 may be in a range from 10 GHz to 80 GHz, from 20 GHz to 80 GHz, or from 30 GHz to 80 GHz.

In some embodiments, the pad 230 may include the signal pad 232, and may further include a ground pad 234. For example, a pair of the ground pads 234 may be disposed with the signal pad 232 interposed therebetween. The ground pads 234 may be electrically separated from the signal pad 232 and the transmission line 220.

In an embodiment, the ground pad 234 may be omitted. The signal pad 232 may be provided as an integral member with an end portion of the transmission line 220.

The signal pad 232 may be electrically connected to the driving integrated circuit chip 250 through the antenna signal wiring 115 of the second circuit board 90. Thus, feeding and driving control to the radiator 210 may be performed through the driving integrated circuit chip 250.

As described above, the signal pad 232 and the antenna signal line 115 may be bonded to each other in the bonding region BR through the conductive intermediate structure 150 such as the anisotropic conductive film (ACF). Bonding stability may be further enhanced by the ground pads 234 around the signal pad 232.

For example, the antenna unit may include silver (Ag), gold (Au), copper (Cu), aluminum (Al), platinum (Pt), palladium (Pd), chromium (Ti), titanium (W), tungsten (Nb), tantalum (Ta), vanadium (V), iron (Fe), manganese (Mn), cobalt (Co), nickel (Ni), zinc (Sn), molybdenum (Mo), calcium (Ca), or an alloy containing at least one thereof. These may be used alone or in a combination of two or more therefrom.

In some embodiments, the antenna unit may include silver (Ag) or a silver alloy (e.g., silver-palladium-copper (APC)), or copper (Cu) or a copper alloy (e.g., a copper-calcium (CuCa)) to implement a low resistance and a fine line width pattern.

In some embodiments, the antenna unit may include a transparent conductive oxide such as indium tin oxide (ITO), indium zinc oxide (IZO), indium zinc tin oxide (ITZO), zinc oxide (ZnOx), etc.

In some embodiments, the antenna unit may include a stacked structure of a transparent conductive oxide layer and a metal layer, and may include, e.g., a double-layered structure of a transparent conductive oxide layer-metal layer, or a triple-layered structure of a transparent conductive oxide layer-metal layer-transparent conductive oxide layer. In this case, flexible property may be improved by the metal layer, and a signal transmission speed may also be improved by a low resistance of the metal layer. Corrosive resistance and transparency may be improved by the transparent conductive oxide layer.

In an embodiment, the antenna unit may include a blackened portion, so that a reflectance at a surface of the radiator 210 may be decreased to suppress a visual pattern recognition due to a light reflectance.

In an embodiment, a surface of the metal layer included in the antenna unit may be converted into a metal oxide or a metal sulfide to form a blackened layer. In an embodiment, a blackened layer such as a black material coating layer or a plating layer may be formed on the metal layer. The black material or plating layer may include silicon, carbon, copper, molybdenum, tin, chromium, molybdenum, nickel, cobalt, or an oxide, a sulfide or an alloy containing at least one therefrom.

A composition and a thickness of the blackened layer may be adjusted in consideration of a reflectance reduction effect and an antenna radiation property.

In some embodiments, the radiator 210 may have a mesh structure. In an embodiment, the transmission line 220 connected to radiator 210 may also have a mesh structure.

As the radiator 210 includes the mesh structure, transmittance may be improved even when the radiator 210 is disposed in a display area of an image display device, and image quality deterioration in the display area by the antenna element 200 may be prevented.

A dummy mesh electrode 240 may be disposed around the radiator 210 and the transmission line 220. The dummy mesh electrode 240 may be electrically and physically spaced apart from the radiator 210 and the transmission line 220 by a separation region 245.

For example, a conductive layer may be formed on the antenna dielectric layer 205. Thereafter, the separation region 245 may be formed along a profile of the radiator 210 and the transmission line 220 while forming the mesh structure by etching the conductive layer.

Distribution of the conductive pattern around the radiator 210 may become uniform by the dummy mesh electrode 240. Accordingly, even when the radiator 210 is disposed in the display area of the image display device, the radiator 210 may be prevented from being visually recognized.

In some embodiments, the pad 230 may be formed in a solid structure to reduce a feeding resistance. For example, the pad 230 may be disposed in a non-display area or a light-shielding area of the image display device. Accordingly, the pad 230 may be disposed at an outside of a user's visible area.

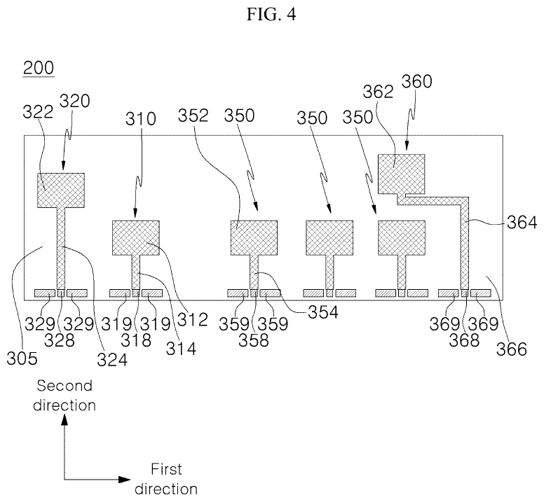

FIG. 4 is a schematic plan view illustrating an antenna element included in an antenna package according to embodiments.

Referring to FIG. 4, the antenna element 200 may include a plurality of antenna units and may be provided as a motion recognition antenna or a radar sensor.

The antenna element 200 may include a transmit antenna unit and a receiving antenna unit group formed on an antenna dielectric layer 305.

The receiving antenna unit group may include a plurality of receiving antenna units. In example embodiments, the receiving antenna unit group may include a first receiving antenna unit 350 and a second receiving antenna unit 360.

The first receiving antenna unit 350 may include a first receiving radiator 352 and a first receiving transmission line 354 extending from the first receiving radiator 352, and may include a first receiving signal pad 358 connected to an end portion of the first receiving transmission line 354. First receiving ground pads 359 may be disposed around the first receiving signal pad 358.

The second receiving antenna unit 360 may include a second receiving radiator 362 and a second receiving transmission line 364 extending from the second receiving radiator 362, and a second receiving signal pad 368 connected to an end portion of the second receiving transmission line 364. Second receiving ground pads 369 may be disposed around the second receiving signal pad 368.

In some embodiments, a plurality of the first receiving antenna units 350 may be arranged to be spaced apart in a single row along a first direction. In an embodiment, three first receiving antenna units 350 may be arranged to be spaced apart in a single row along the first direction

For example, the second receiving antenna unit 360 may be disposed to be spaced apart from the first receiving radiator 352 included in at least one of a plurality of the first receiving antenna units 350 in a second direction. The first direction and the second direction correspond to a width direction and a length direction of the antenna dielectric layer 305, respectively, and may be perpendicular to each other.

In an embodiment, the second receiving radiator 362 may be spaced apart from the first receiving radiator 352 included in the first receiving antenna unit 350 farthest from the first transmit antenna unit 310 among a plurality of the first receiving antenna units 350 in the second direction.

The second receiving transmission line 364 may have a bent shape to bypass the first receiving antenna unit 350.

In some embodiments, a plurality of the transmit antenna units may be arranged. Accordingly, a transmit antenna unit group may be defined. The transmit antenna unit group and the receiving antenna unit group may be spaced apart by a predetermined distance in the first direction.

The transmit antenna unit group may include a first transmit antenna unit 310 and a second transmit antenna unit 320. The first transmit antenna unit 310 may have a length smaller than a length of the second transmit antenna unit 320 (a length in the second direction). The first transmit antenna unit 310 may be closer to the receiving antenna unit group in the first direction than the second transmit antenna unit 320.

The first transmit antenna unit 310 may include a first transmit radiator 312 and a first transmit transmission line 314 extending from the first transmit radiator 312, and may include a first transmission signal pad 318 connected to an end portion of the first transmit transmission line 314. First transmit ground pads 319 may be disposed around the first transmission signal pad 318.

The second transmit antenna unit 320 may include a second transmit radiator 322 and a second transmit transmission line 324 extending from the second transmit radiator 322, and may include a second transmit signal pad 328 connected to an end portion of the second transmit transmission line 324. Second transmit ground pads 329 may be disposed around the second transmit signal pad 328.

The antenna element 200 may detect a signal at two orthogonal axes (a first axis in the first direction and a second axis in the second direction). For example, the antenna element 200 may transmit a change in signal strength in two orthogonal directions to the driving integrated circuit chip 250 including a motion sensor driving circuit or a radar processor. The driving circuit or processor may measure positional changes or distances in all directions on an X-Y coordinate system based on the collected information.

For example, the antenna element 200 may be provided as a motion sensor that detects motion or gestures on two axes perpendicular to each other, or may be used as a radar for detecting a distance. For example, a signal transmitted from the transmit antenna unit may be reflected from a sensing object, and the receiving radiators 352 and 362 may receive the signal reflected from the sensing object.

For example, among a plurality of the first receiving antenna units 350, the first receiving radiator 352 of the first receiving antenna unit which is disposed in an area where the first axis and the second axis intersect may serve as a reference point for measuring the change in signal intensity. For example, a change in the position of the sensing object may be detected by measuring the change in signal intensity at the first axis and the second axis based on a signal intensity of the first receiving radiator 352 disposed at the intersection point.

In some embodiments, each of the transmit radiators 312 and 322, and the receiving radiators 352 and 362 may be designed to have a resonance frequency in a high frequency or ultra-high frequency band, e.g., 3G, 4G, 5G, or more. In an embodiment, the resonance frequency of each of the transmit radiators 312 and 322 and the receiving radiators 352 and 362 may be about 50 GHz or more, e.g., in a range from 50 GHz to 80 GHZ, or from 55 GHz to 77 GHz.

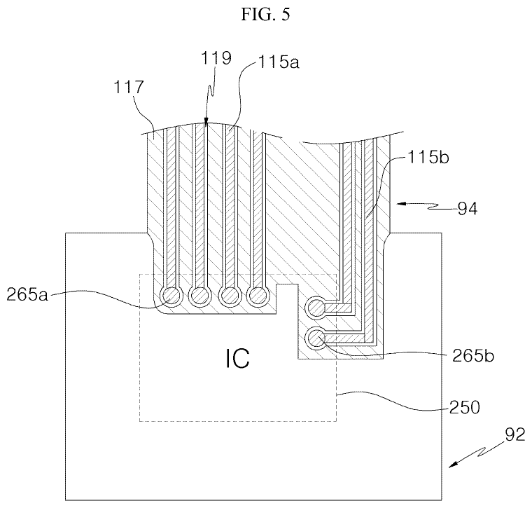

FIG. 5 is a partially enlarged view schematically illustrating an antenna package including an antenna circuit board stack according to embodiments.

Referring to FIG. 5, the second circuit board 90 of the antenna package may be bonded to the antenna element 200 described with reference to FIG. 4. In this case, the antenna signal wiring 115 may include a transmit signal wiring 115a and receiving signal wirings 115b.

In some embodiments, one end portion of each of the transmit signal wirings 115a may be bonded to each of the transmit signal pads 318 and 328. One end portion of each of the receiving signal wirings 115b may be connected to each of the receiving signal pads 358 and 368, respectively.

The antenna connection terminals 260 may include transmit connection terminals 265a and receiving connection terminals 265b. The other end portions of each of the transmit signal wirings 115a may be connected (e.g., by soldering) to each of the transmit connection terminals 265a. The other end portions of the receiving signal wirings 115b may be connected (e.g., by soldering) to each of the receiving connection terminals 265b.

In some embodiments, the first conductive layer 110 may include a horizontal ground layer 117. The horizontal ground layer 117 may be physically and electrically separated from the antenna signal wirings 115a and 115b with a spaced region 119 interposed therebetween.

The horizontal ground layer 117 may shield noises around the antenna signal wirings 115a and 115b, and may promote signal/feeding through the antenna signal wirings 115a and 115b.

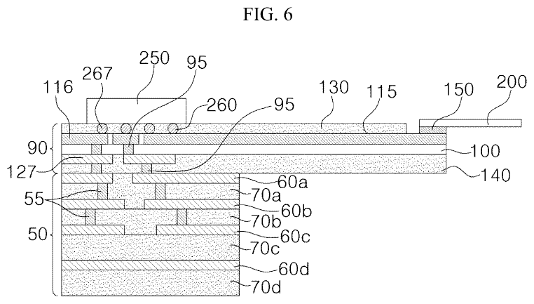

FIG. 6 is a schematic cross-sectional view illustrating an antenna package according to embodiments.

Referring to FIG. 6, connection terminals of the driving integrated circuit chip 250 may further include internal circuit terminals 267 together with the antenna connection terminal 260. For example, the internal circuit terminals 267 may be connected to internal wirings of the circuit board such as a power line, a logic line, etc.

The first conductive layer 110 and the second conductive layer 120 of the second circuit board 90 may each include second internal wirings 116 and 127, and wiring layers 60a to 60d of the first circuit board 50 may include first internal wirings. The first and second internal wirings may include the power line and the logic lines.

The first circuit board 50 may include a first via structure 55, and the second circuit board 90 may include a second via structure 95. The internal circuit terminal 267 of the driving integrated circuit chip 250 may be connected to the second and first internal wirings through the second via structure 95 and the first via structure 55.

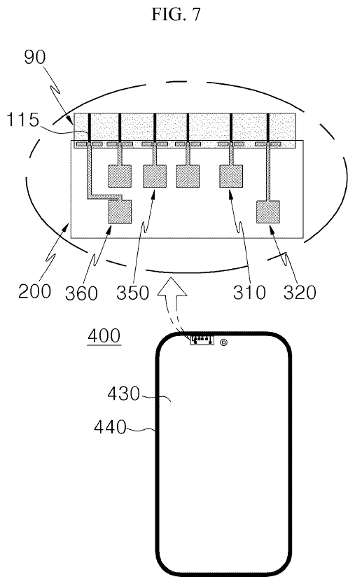

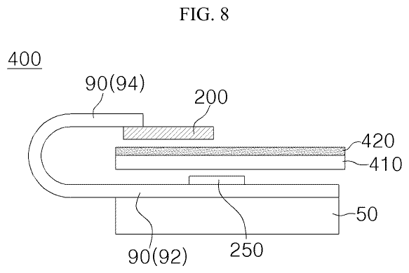

FIG. 7 is a schematic plan view describing an image display device according to embodiments. FIG. 8 is a schematic cross-sectional view describing an image display device according to embodiments.

Referring to FIGS. 7 and 8, a front portion of the image display device 400 may include a display area 430 and a non-display area 440. The non-display area 440 may correspond to, e.g., a light-shielding portion or a bezel portion of the image display device 400.

The antenna element 200 according to embodiments may be disposed toward the front portion of the image display device 400, and may be disposed on, e.g., a display panel 410. Accordingly, the antenna element 200 may be applied as an antenna-on-display (AOD) element.

The antenna element 200 may be formed over the display area 430 and the non-display area 440 of the image display device 400. The radiator 210 of the antenna element 200 may at least partially overlap the display area 430. The pads 230 of the antenna element 200 may overlap the non-display area 440.

A portion of the antenna element 200 located in the display area 430 may have a mesh structure, and a portion (e.g., the pad) located in the non-display area 440 may have a solid structure. In an embodiment, the transmission line 220 may include a mesh structure and may partially include a solid structure.

An optical layer 420 may be further included on the display panel 410. For example, the optical layer 420 may be a polarizing layer including a polarizer or a polarizing plate.

In an embodiment, a cover window may be disposed on the antenna element 200. The cover window may include, e.g., an ultra-thin glass (UTG) or a transparent resin film. Accordingly, an external impact applied to the antenna element 200 may be reduced or buffered.

For example, the antenna element 200 may be disposed between the optical layer 420 and the cover window. In this case, the antenna dielectric layer 205 and the optical layer 420 disposed under the radiator 210 may be provided as the dielectric layer of the radiator 210. Accordingly, a proper dielectric constant may be achieved so that motion sensing performance of the antenna element 200 may be sufficiently implemented.

An end portion of the second portion 94 of the second circuit board 90 may be bonded to the antenna element 200, and the driving integrated circuit chip 250 may be mounted on the first portion 92 of the second circuit board 90. The second circuit board 90 may be bent along a side bending profile of the display panel 410 using the second portion 94 of the second circuit board 90.

Accordingly, the first circuit board 50 and the driving integrated circuit chip 250 may be disposed on a rear portion of the image display device 400. The first circuit board 50 may be provided as a main board of the image display device 400. In an embodiment, a circuit element such as an RLC element or a control circuit element such as an AP chip may be mounted on a bottom surface of the first circuit board 50.

Hereinafter, experimental examples including specific embodiments and comparative examples are presented to help the understanding of the present invention, but this only exemplifies the present invention and does not limit the scope of the attached patent claims, and it is clear to those skilled in the art that various changes and modifications to the embodiment can be made within the scope of the present invention and technical ideas, and it is natural that these modifications and modifications belong to the attached patent claims.

### Example and Comparative Example

### Example

A stack of the first circuit board 50 and the second circuit board 90 having the structure illustrated in FIG. 1 was prepared, and the driving integrated circuit chip 250 was mounted on the second circuit board 90. The antenna element 200 having the structure illustrated in FIG. 4 was bonded to an end portion of the second circuit board 90.

### Comparative Example

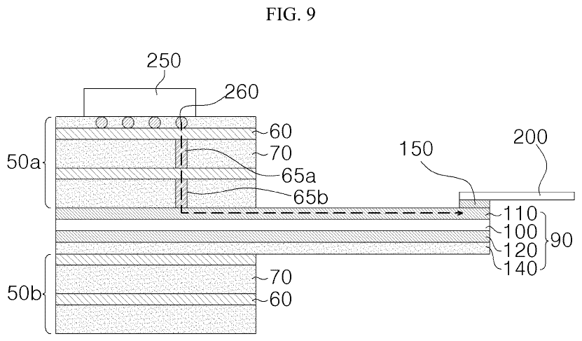

An antenna package of Comparative Example having the structure illustrated in FIG. 9. Specifically, the second circuit board 90 was inserted as an intermediate layer of the first circuit board 50. Accordingly, the first circuit board 50 was separated into a first lower circuit board 50b disposed under the second circuit board 90 and a first upper circuit board 50a disposed on the second circuit board 90.

The via structures 65a and 65b were additionally formed in the insulating layer 70 of the first upper circuit board 50a to connect the first conductive layer 110 and the antenna connection terminal 260.

An antenna package having the same structure as that of Example was manufactured except for the above-described board arrangement/via structure formation.

### Experimental Example: Evaluation of Signal Loss

A signal loss (S21) of each antenna unit was measured while supplying the same predetermined power to the antenna element 200 through the driving integrated circuit chip 250 of the antenna packages of Example and Comparative Example.

The measurement results are shown in Table 1 below.

TABLE 1

| | S21(dB) | | | | | |
|---|---|---|---|---|---|---|
| | | | first | second | third | fourth |
| | first | second | re- | re- | re- | re- |
| | transmit | transmit | ceiving | ceiving | ceiving | ceiving |
| | antenna | antenna | antenna | antenna | antenna | antenna |
| | unit | unit | unit | unit | unit | unit |
| Example | −1.85 | −2.16 | −1.54 | −1.55 | −1.54 | −1.55 |
| Compar- | −3.3 | −3.56 | −3 | −3.02 | −3.05 | −3.06 |
| ative | | | | | | |
| Example | | | | | | |

Referring to Table 1, the antenna feeding was performed with entirely low signal loss in the antenna units included in the antenna package of Example. In Comparative Example, as indicated by a dotted arrow in FIG. 9, as the driving integrated circuit chip 250 and the first conductive layer 110 of the second circuit board 90 was connected through the via structure, the signal loss was significantly increased.

1. An antenna package, comprising:
a first circuit board;
a second circuit board stacked on a top surface of the first circuit board, the second circuit board having a ductility higher than that of the first circuit board;
an antenna driving integrated circuit chip mounted on the second circuit board; and
an antenna element bonded to the second circuit board and electrically connected to the antenna driving integrated circuit chip.

2. The antenna package of claim 1, wherein the second circuit board is a flexible printed circuit board, and the first circuit board is a rigid printed circuit board.

3. The antenna package of claim 1, wherein the first circuit board comprises repeatedly stacked insulating layers and wiring layers, and
wherein the second circuit board comprises a core layer, and a first conductive layer formed on a top surface of the core layer, and the first conductive layer comprises an antenna signal wiring bonded to the antenna element.

4. The antenna package of claim 3, wherein the insulating layer of the first circuit board has a higher hardness or a lower ductility than that of the core layer of the second circuit board.

5. The antenna package of claim 3, wherein the driving integrated circuit chip is directly mounted on the antenna signal wiring.

6. The antenna package of claim 3, wherein the second circuit board further comprises a barrier layer covering the antenna signal wiring.

7. The antenna package of claim 6, wherein the second circuit board has a first portion overlapping the first circuit board and a second portion that does not overlap the first circuit board, and
the barrier layer is formed throughout the first portion and the second portion.

8. The antenna package of claim 7, wherein an end portion of the second portion of the second circuit board has a bonding region bonded to the antenna element, and
the barrier layer is spaced apart from the bonding region with a gap therebetween on the second portion of the second circuit board

9. The antenna package of claim 6, wherein the driving integrated circuit chip comprises antenna connection terminals connected to the antenna signal wiring, and the barrier layer is filled between the antenna connection terminals.

10. The antenna package of claim 3, wherein the antenna element comprises an antenna dielectric layer and a plurality of antenna units formed on the antenna dielectric layer, and
the antenna signal wiring of the second circuit board includes a plurality of antenna signal wirings connected to each of the antenna units.

11. The antenna package of claim 10, wherein the antenna units comprise at least one transmit antenna unit and a plurality of receiving antenna units.

12. The antenna package of claim 10, wherein the first conductive layer further comprises a horizontal ground layer spaced apart from the antenna signal wirings and arranged around the antenna signal wirings.

13. The antenna package of claim 3, wherein the second circuit board further comprises a second conductive layer formed on a bottom surface of the core layer to overlap the antenna signal wirings.

14. The antenna package of claim 3, wherein the driving integrated circuit chip comprises an antenna connection terminal connected to the antenna signal wiring, and an internal circuit terminal connected to the wiring layer.

15. The antenna package of claim 14, wherein the first circuit board and the second circuit board each further comprises a via structure connecting the internal circuit terminal to the wiring layer.

16. An image display device, comprising:
a display panel; and
the antenna package of claim 1 coupled to the display panel so that the antenna element is arranged toward a front portion of the display panel.

17. The image display device of claim 16, wherein the first circuit board and the driver integrated circuit chip are arranged at a rear portion under the display panel, and the second circuit board is bent to the front portion of the display panel and bonded to the antenna element.
